(19) United States
(12) Patent Application Publication
(10) Pub. No.: US 2022/0093373 A1
(43) Pub. Date: Mar. 24, 2022

(54) METHOD FOR RESIDUE NON-UNIFORMITY MODULATION

(71) Applicant: Applied Materials, Inc., Santa Clara, CA (US)

(72) Inventor: Mingle Tong, Sunnyvale, CA (US)

(73) Assignee: Applied Materials, Inc., Santa Clara, CA (US)

(21) Appl. No.: 17/026,792

(22) Filed: Sep. 21, 2020

(51) Int. Cl. H01J 37/32; C23C 16/50; C23C 16/458

(52) U.S. Cl. CPC H01J 37/32715; H01J 37/3244; H01L 21/67069; C23C 16/4584; C23C 16/50

(57) ABSTRACT

Exemplary semiconductor processing systems may include a chamber body having sidewalls and a base. The systems may include a substrate support extending through the base of the chamber body. The substrate support may include a support plate. The substrate support may include a shaft coupled with the support plate. The chambers may include a bottom plate coupled with the shaft of the substrate support and extending below a bottom surface of the support plate. The bottom plate may include a first emissivity zone and a second emissivity zone. The first emissivity zone and the second emissivity zone may have different emissivity levels.

### TECHNICAL FIELD

The present technology relates to components and apparatuses for semiconductor manufacturing. More specifically, the present technology relates to processing chamber components and other semiconductor processing equipment.

### BACKGROUND

Integrated circuits are made possible by processes which produce intricately patterned material layers on substrate surfaces. Producing patterned material on a substrate requires controlled methods for forming and removing material. Precursors are often delivered to a processing region and distributed to uniformly deposit or etch material on the substrate. Many aspects of a processing chamber may impact process uniformity, such as uniformity of process conditions within a chamber, uniformity of flow through components, as well as other process and component parameters. Even minor discrepancies across a substrate may impact the formation or removal process.

Thus, there is a need for improved systems and methods that can be used to produce high quality devices and structures. These and other needs are addressed by the present technology.

### SUMMARY

Exemplary semiconductor processing systems may include a chamber body including sidewalls and a base. The systems may include a substrate support extending through the base of the chamber body. The substrate support may include a support plate configured to support a semiconductor substrate. The substrate support may include a shaft coupled with the support plate. The systems may include a bottom plate coupled with the shaft of the substrate support and may extend below a bottom surface of the support plate. The bottom plate may include a first emissivity zone and a second emissivity zone. The first emissivity zone and the second emissivity zone may have different emissivity levels.

In some embodiments, one or both of the first emissivity zone and the second emissivity zone may extend radially from a center of the bottom plate. The first emissivity zone may include a polished top surface. The first emissivity zone may include a textured top surface. The first emissivity zone may include a first material and the second emissivity zone may include a different second material. One or both of the first emissivity zone and the second emissivity zone may be shaped based on a known residue pattern of a semiconductor substrate. A distance between a bottom surface of the support plate and the first emissivity zone may be different than a distance between the bottom surface of the support plate and the second emissivity zone. The systems may include a drive mechanism that selectively rotates the bottom plate about the shaft to change an angular position of the first emissivity zone and the second emissivity zone a drive mechanism that selectively rotates the bottom plate about the shaft to change an angular position of the first emissivity zone and the second emissivity zone. The bottom plate may be coupled with an inner magnet assembly. The drive mechanism may include an outer magnet assembly. The outer magnet assembly may interact with the inner magnet assembly to drive rotation of the bottom plate. Rotation of the outer magnet assembly may cause the inner magnet assembly and the bottom plate to rotate. One or both of the inner magnet assembly and the outer magnet assembly may include an electromagnet.

Some embodiments of the present technology may encompass methods of semiconductor processing. The methods may include flowing one or more precursors into a processing chamber. The processing chamber may include a substrate support. The substrate support may include a support plate that supports a semiconductor substrate. The substrate support may include a shaft coupled with the support plate. The processing chamber may include a bottom plate coupled with the shaft of the substrate support and that extends below a bottom surface of the support plate. The bottom plate may include a first emissivity zone and a second emissivity zone. The first emissivity zone and the second emissivity zone may have different emissivity levels. The methods may include generating a plasma of the precursor within the processing chamber. The methods may include depositing a material on the semiconductor substrate.

In some embodiments, the methods further comprise rotating the bottom plate about the shaft to change an angular position of the first emissivity zone and the second emissivity zone. Rotating the bottom plate about the shaft may include repositioning the first emissivity zone to a first location for a first period of time and repositioning the first emissivity zone to a second location for a second period of time after the first period of time has elapsed. The processing chamber may include a drive mechanism having an outer magnet assembly. The bottom plate may be coupled with an inner magnet assembly. Rotating the bottom plate about the shaft may include rotating the outer magnet assembly to cause the inner magnet assembly and the bottom plate to rotate. The processing chamber may include a drive mechanism having an outer magnet assembly. The bottom plate may be coupled with an inner magnet assembly. One or both of the inner magnet assembly and the outer magnet assembly may include an electromagnet. Rotating the bottom plate about the shaft may include powering the electromagnet to rotate the inner magnet assembly and the bottom plate. A timing of rotation of the bottom plate may be based on a residue pattern of the material on the semiconductor substrate. The first emissivity zone may be formed from a first plurality of light emitting diodes directed toward the substrate support. The second emissivity zone may be formed from a second plurality of light emitting diodes directed toward the substrate support. The methods may further include adjusting a power level of one or both of the first plurality of light emitting diodes and the second plurality of light emitting diodes to adjust an emissivity pattern of the bottom plate.

Some embodiments of the present technology may encompass semiconductor processing systems. The systems may include a chamber body having sidewalls and a base. The systems may include a substrate support extending through the base of the chamber body. The substrate support may include a support plate. The substrate support may include a shaft coupled with the support plate. The systems may include a bottom plate coupled with the shaft of the substrate support and that extends below a bottom surface of the support plate. A top surface of the bottom plate may include a plurality of light emitting diodes (LEDs) that emit infrared light toward the substrate support. In some embodiments, each of the plurality of light emitting diodes may be independently controllable.

Such technology may provide numerous benefits over conventional systems and techniques. For example, embodiments of the present technology may improve temperature uniformity and film uniformity across a substrate. Additionally, the components may allow modification to accommodate any number of chambers or processes. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic cross-sectional view of an exemplary processing chamber according to some embodiments of the present technology.

FIG. 4 shows a schematic top plan view of a bottom plate according to some embodiments of the present technology.

FIG. 5 shows a schematic cross-sectional view of an exemplary processing chamber according to some embodiments of the present technology.

FIGS. 6A and 6B show schematic top plan views of exemplary bottom plates according to some embodiments of the present technology.

FIG. 7A shows schematic cross-sectional view of an exemplary bottom plate according to some embodiments of the present technology.

FIG. 7B shows a schematic top plan view of the bottom plate of FIG. 7A according to some embodiments of the present technology.

FIG. 8 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

As device features reduce in size, tolerances across a substrate surface may be reduced, and material property differences across a film may affect device realization and uniformity. Many chambers include a characteristic process signature, which may produce residual non-uniformity across a substrate. Temperature differences, flow pattern uniformity, and other aspects of processing may impact the films on the substrate, creating film uniformity differences across the substrate for materials produced or removed. For example, turbulent deposition gas flow and/or misalignment of apertures of a blocker plate and faceplate of a gas box may lead to non-uniform flow of deposition gases. Additionally, in some embodiments a substrate support or heater on which a substrate is disposed may include one or more heating mechanisms to heat a substrate. When heat is delivered or lost differently between regions of a substrate, the film deposition may be impacted where, for example, warmer portions of the substrate may be characterized by thicker deposition or different film properties relative to cooler portions. This temperature non-uniformity may be attributable, for example, to temperature fluctuations about the shaft of the pedestal.

The present technology overcomes these challenges during these higher temperature processes, as well as for any other process that may benefit from improved temperature uniformity. By utilizing a shield having different emissivity zones, increased control of heat loss within any particular chamber may be afforded. Accordingly, the present technology may produce improved film deposition characterized by improved thickness and material property uniformity across a surface of the substrate.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

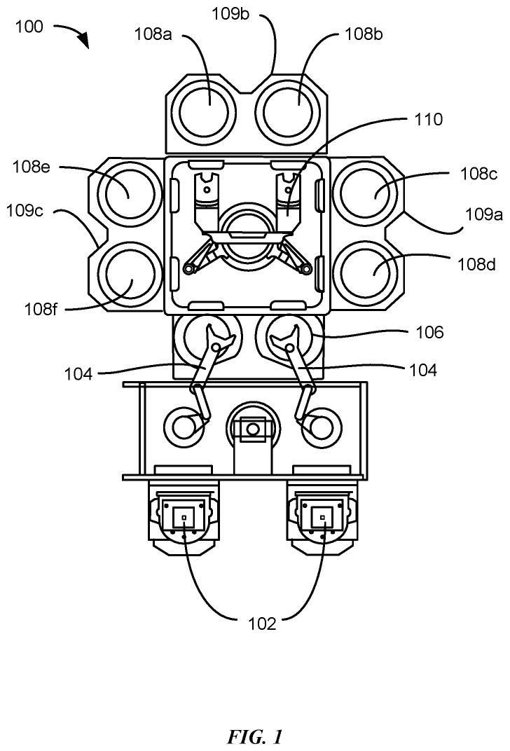

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

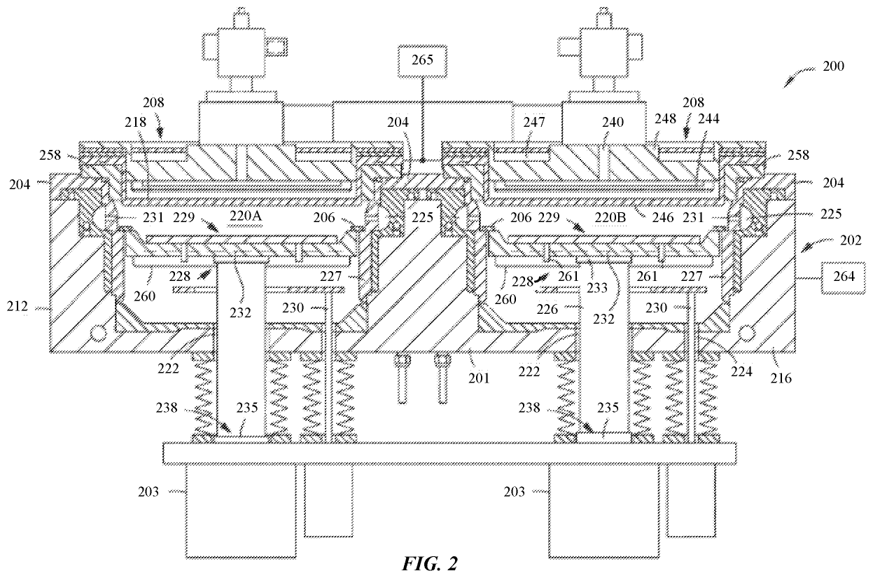

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

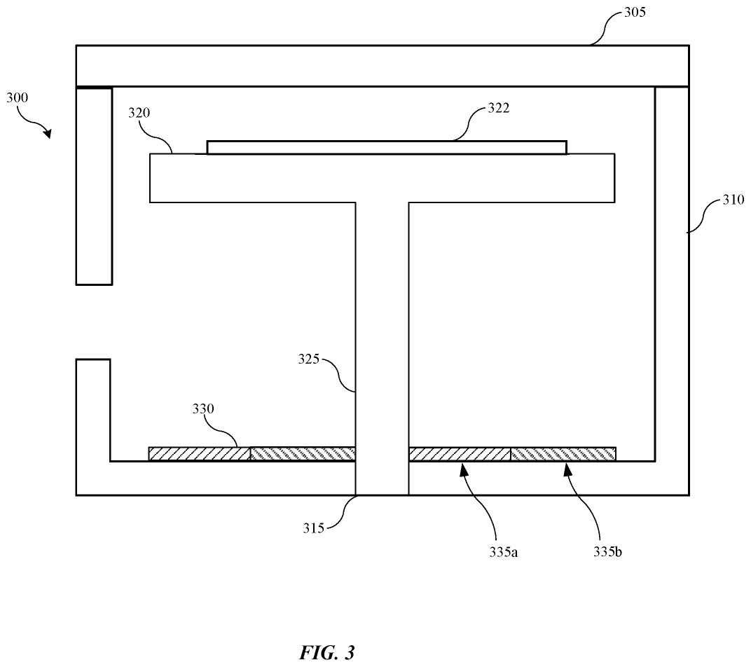

FIG. 3 shows a schematic partial cross-sectional view of an exemplary processing system 300 according to some embodiments of the present technology. FIG. 3 may illustrate further details relating to components in system 200, such as for pedestal 228. System 300 is understood to include any feature or aspect of system 200 discussed previously in some embodiments. The system 300 may be used to perform semiconductor processing operations including deposition of hardmask materials as previously described, as well as other deposition, removal, and cleaning operations. System 300 may show a partial view of the chamber components being discussed and that may be incorporated in a semiconductor processing system. Any aspect of system 300 may also be incorporated with other processing chambers or systems as will be readily understood by the skilled artisan.

System 300 may include a processing chamber including a faceplate 305, through which precursors may be delivered for processing, and which may be coupled with a power source for generating a plasma within the processing region of the chamber. The chamber may also include a chamber body 310, which as illustrated may include sidewalls and a base. A pedestal or substrate support 315 may extend through the base of the chamber as previously discussed. The substrate support may include a support plate 320, which may support semiconductor substrate 322. The support plate 320 may be coupled with a shaft 325, which may extend through the base of the chamber.

As previously explained, thermal uniformity may be challenged in any processing chamber, and for higher temperature processes, radiative losses may be substantially greater. Continuing the non-limiting example explained previously, some carbon-film deposition may be performed at temperatures above 600° C., or higher, which may facilitate adsorption of carbon radicals on a surface of the substrate. To maintain these processing temperatures, the substrate support, such as substrate support 315, may include one or more heating elements, which may be enabled to produce substrate or plate temperatures that may be greater than or about 500° C., and may be greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., greater than or about 750° C., greater than or about 775° C., greater than or about 800° C., or higher.

While the semiconductor substrate 322 and aspects of the support may be maintained at higher temperatures, the chamber body 310 may be maintained at lower temperatures, such as below or about 100° C. or lower. This may create a heat sink that can affect the temperature profile across the substrate 322. For example, edge regions of the substrate 322 or support plate 320 may have higher losses to the sidewalls of the chamber, which may lower a substrate temperature radially about the substrate 322. This lower temperature in a radial band may produce a first kind of non-uniformity, which may exist in a band about the substrate 322. Similarly, as illustrated in the figure, a slit valve or chamber access may be positioned or defined through a portion of the chamber body. This access may be characterized by a lower temperature than other aspects of the chamber body, which may create a localized heat sink. This lower temperature in a region may create a planar non-uniformity, where a section of substrate 322 may be characterized by lower temperature.

Temperature at the substrate 322 may be closely correlated to the extinction coefficient of the film, accordingly, temperature fluctuations across the film, which may result in thickness variations, may also result in extinction coefficient variation across the film, which may impact subsequent lithography or etching operations.

System 300 may also incorporate a bottom plate 330, such as a heat shield or radiation shield, which may be coupled about or with the shaft 325 of the substrate support 315. Bottom plate 330 may be vertically spaced apart from the bottom of the support plate 320. For example, the bottom plate 330 may be positioned between about 2 mm and about 30 mm from the bottom of the support plate 320. The bottom plate 330 incorporated below the support plate 320 may at least partially protect against the thermal variation from radiative heat losses. For example, the bottom plate 330 may include multiple emissivity zones 335a and 335b. Each of the emissivity zones 335a, 335b may have a different emissivity level to reflect different amounts of heat back to the support plate 320 at various positions. The emissivity zones 335a and 335b may be sized, shaped, and positioned to control the temperature of the semiconductor substrate 322 to improve temperature uniformity and/or otherwise reduce residual non-uniformity on the semiconductor substrate 322. As illustrated, the emissivity zones 335a and 335b are concentrically arranged annular zones. However, it will be appreciated that emissivity zones of other shapes and arrangements may be utilized. For example, the emissivity zones 335a and 335b of the bottom plate 330 may be radial shapes (such as wedges), linear strips, symmetrical patterns, asymmetrical patterns, regular shapes, irregular shapes, and/or any other shapes to improve the residual uniformity of the semiconductor substrate 322. It will be appreciated that while illustrated with two emissivity zones 335a and 335b, the bottom plate 330 may include any number of emissivity zones. For example, the bottom plate 330 may include about or greater than 2 emissivity zones, about or greater than 3 emissivity zones, about or greater than 4 emissivity zones, about or greater than 5 emissivity zones, about or greater than 6 emissivity zones, about or greater than 7 emissivity zones, about or greater than 8 emissivity zones, about or greater than 9 emissivity zones, or more.

Various techniques may be utilized to provide emissivity zones with various emissivity levels. For example, different emissivity levels may be achieved by texturing emissivity zones differently from one another. A first emissivity zone may have a polished upper surface that has a low emissivity which reflects heat back to the support plate 320, while a second emissivity zone may have a rough and/or otherwise textured upper surface that has a high emissivity and which absorbs more heat. Various types of surface textures may be applied to the upper surface of the bottom plate 330 to create various emissivity levels. For example, the surface may be engraved, milled, laser etched, sandblasted, and/or otherwise treated to apply bumps, grooves (straight and/or curved), ridges (straight and/or curved), and/or other textures. The depth of grooves, height of ridges and/or bumps, and/or cross-sectional shape (v-shape, u-shape, etc.) of any bumps, grooves, and/or ridges may be used to tailor the emissivity level of a particular emissivity zone to a desired level to produce a more uniform film deposition on the semiconductor substrate 322.

In some embodiments, one or more portions of a top surface of the bottom plate 330 may be raised or lowered in various emissivity zones. The variance in height of the various emissivity zones results in differences in distance between a bottom surface of the support plate 320 and the top surfaces of the various emissivity zones, which affects how much heat is reflected back to the support plate 320 at the locations of the emissivity zones. For example, emissivity zones that are closer to the bottom surface of the support plate 320 may result in greater amounts of heat being received at the bottom surface of the support plate 320 than from emissivity zones that are spaced further from the bottom surface, as the reduced distance between the emissivity zones and the bottom surface of the support plate 320 reduces the heat loss of the reflected heat.

In some embodiments, the emissivity level may be determined based on the material used to form each emissivity zone. For example, the bottom plate 330 may include a number of materials with different emissivity coefficients to form a number of emissivity zones with different emissivity levels. For example, a low emissivity area may include materials with low emissivity coefficients (oftentimes about or between 0 and 0.50, more commonly between about 0.1 and 0.3), which may include reflective metals and minerals, while a high emissivity area may include materials with high emissivity coefficients (oftentimes about or between 0.51 and 1, more commonly between about 0.7 and 0.9), which may include less ceramics, roughened metals, oxidized metals, anodized metals, carbon finishes, silica, and the like. It will be appreciated that the bottom plate 330 may include any combination of any number of materials to achieve a desired size, shape, and arrangement of emissivity patterns to increase the uniformity of residue on the semiconductor substrate 322.

In some embodiments, only a single technique (material, surface finish, surface height, etc.) for controlling the emissivity level of a particular emissivity zone and/or bottom plate 330 may be utilized, while in other embodiments any combination of techniques for controlling the emissivity level of a particular emissivity zone and/or bottom plate 330 may be utilized. As just one example, a first emissivity zone 335a may include a polished metallic surface to provide low emissivity to heat a portion of the support plate 320 while a second emissivity zone 335b may have a roughened ceramic surface that is lower than the first emissivity zone 335a to provide high emissivity and to radiate less heat back toward a portion of the support plate 320.

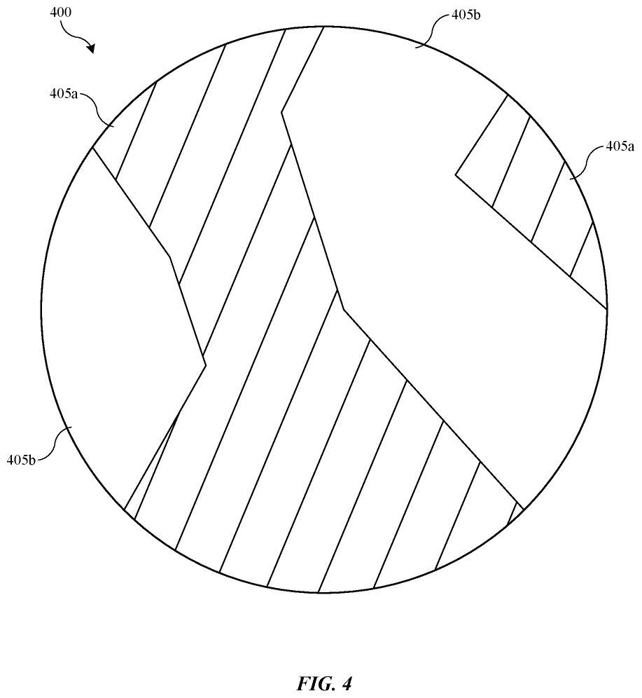

FIG. 4 shows a schematic top plan view of an exemplary bottom plate 400 according to some embodiments of the present technology. The bottom plate 400 may be included in any chamber or system previously described (such as system 200 or 300), as well as any other chamber or system that may benefit from the shielding. When processing semiconductor substrates with a fixed recipe, a film residue pattern should be stable substrate to substrate. With a known residue pattern, the bottom plate 400 may be designed with emissivity zones that mimic the known residue pattern in order to improve the uniformity of residue on the semiconductor substrate. For example, a residue map of the residue deposition on semiconductor substrates processed with the fixed recipe may indicate sizes, shapes, and positions of areas of low and high film deposition on the substrates. The bottom plate 400 may include emissivity zones 405 that are designed to raise deposition in low areas and/or to lower deposition in high areas to achieve better deposition uniformity across a semiconductor substrate.

For example, emissivity zones with low emissivity levels and/or high emissivity levels may be provided on the bottom plate 400 in areas that correspond with areas in which the residue map indicated non-uniformity (high and/or low film thickness) of the film residue on the semiconductor substrate to reflect different amounts of heat back to the support plate, which raises and/or lowers the temperature of the semiconductor substrate in desired areas to even out the deposition film. The temperature changes to the semiconductor substrate are typically about or greater than 0.5° C., about or greater than 1.0° C., about or greater than 1.5° C., about or greater than 2.0° C., about or greater than 2.5° C., about or greater than 3.0° C., about or greater than 3.5° C., about or greater than 4.0° C., about or greater than 4.5° C., or more, with the actual temperature change to the semiconductor substrate depending on a temperature of the heater. Higher temperature processes may have greater radiative heat losses that can be reflected back using the bottom plate 400.

For example, as illustrated, the bottom plate 400 includes low emissivity zones 405a and high emissivity zones 405b. As illustrated, two low emissivity zones 405a and two high emissivity zones 405b are provided on the bottom plate 400. As illustrated, each emissivity zone 405 has an irregular shape that is designed to generate more uniform film deposition on a semiconductor substrate. For example, the low emissivity zones 405a and high emissivity zones 405b may be positioned to match known low and high film thickness areas of a given deposition recipe. The low emissivity zones 405a may be placed in areas of the bottom plate 400 that correspond to areas of the semiconductor substrate that have thinner film deposition. These low emissivity zones 405a may reflect greater levels of heat back to the support plate and the semiconductor substrate to help increase film deposition at these areas. High emissivity zones 405b may be placed in areas of the bottom plate 400 that correspond to areas of the semiconductor substrate that have thicker film deposition. These high emissivity zones 405b may absorb greater levels of heat to help decrease film deposition at these areas. As noted above, the emissivity levels of the various emissivity zones 405 may be achieved using a number of different techniques, such as by adjusting the relative heights of the various emissivity zones 405, using different materials with different emissivity coefficients in different emissivity zones 405, and/or by applying different surface finishes to the bottom plate 400 in each of the emissivity zones 405. As the low emissivity zones 405a and high emissivity zones 405b are sized, shaped, and positioned to create more uniform film deposition on a semiconductor substrate, the size, shape, position, emissivity, and number of emissivity zones may be adapted to meet a particular film deposition map for a given recipe.

While described in terms of “high” emissivity and “low” emissivity, a person of skill in the art will understand that the high emissivity zones 405b may not have a particular emissivity coefficient (i.e., over 0.50), but instead may be understood to have higher emissivity than the low emissivity zones 405a. Similarly, the low emissivity zones 405a are not constrained to a particular emissivity coefficient range, but rather are defined relative to the emissivity of other zones. In some embodiments, all emissivity zones 405 on a faceplate 400 may have emissivity coefficients that are less than 0.50 or greater than 0.50. Additionally, while shown with two low emissivity zones 405a and two high emissivity zones 405b, it will be appreciated that any combination of low and/or high emissivity zones may be provided on the bottom plate 400 to generate more uniform plasma deposition on a semiconductor substrate. In some embodiments, all of the emissivity zones of a given type (high or low) may have the same emissivity level. In other embodiments, some or all of the low emissivity zones 405a may have different emissivity levels than other low emissivity ones 405a. Similarly, some or all of the high emissivity zones 405b may have different emissivity levels than other high emissivity ones 405b.

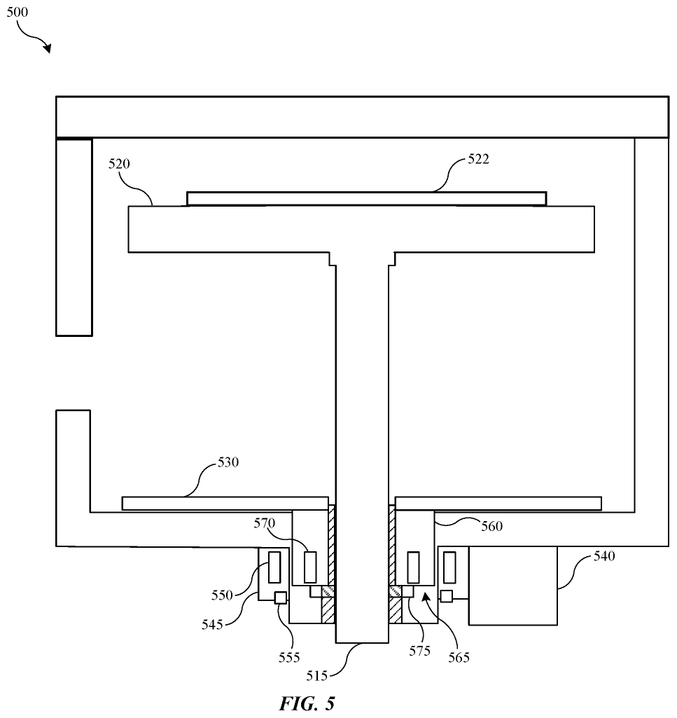

FIG. 5 shows a schematic cross-sectional view of an exemplary processing chamber 500 according to some embodiments of the present technology. FIG. 5 may include one or more components discussed above with regard to FIGS. 2 and 3, and may illustrate further details relating to that chamber. Chamber 500 is understood to include any feature or aspect of system 200 and/or system 300 discussed previously. Chamber 500 may show a partial view of a processing region of a semiconductor processing system, and may not include all of the components, and which are understood to be incorporated in some embodiments of chamber 500. Chamber 500 may include a substrate support 515 that includes a support plate 520, which may support a semiconductor substrate 522. The substrate support 515 may also include a shaft 525 which may extend through the base of the chamber 500.

Chamber 500 may also incorporate a bottom plate 530, such as a heat shield or radiation shield, which may be coupled about or with the shaft 525 of the substrate support 515. Bottom plate 530 may be vertically spaced apart from the bottom of the support plate 520. The bottom plate 530 may be similar to bottom plates 330 and 400 described above. For example, the bottom plate 530 may include multiple emissivity zones that have a different emissivity level to reflect different amounts of heat back to the support plate 520. In some embodiments, rather than using a static emissivity pattern a semiconductor processing system may implement a dynamic emissivity pattern. Such dynamic systems may be achieved using various techniques. For example, as illustrated in FIG. 5, the bottom plate 530 may be rotatably coupled about the shaft 525. During semiconductor processing, the bottom plate 530 may be rotated at various points in time to move one or more emissivity patterns of the bottom plate 530 to a desired position to reflect heat back toward a particular location of the support plate 520 and semiconductor substrate 522. This enables a bottom plate 530 having a fixed emissivity pattern to be used to generate a more uniform film deposition profile across the semiconductor substrate 522. For example, the bottom plate 530 may include at least one high and one low emissivity zone. In some embodiments, at least one of the emissivity zones has a radial design, such as a wedge and/or radial strip. The radial emissivity zone may be rotated about the shaft 525 to different locations for set periods of time to generate a uniform film deposition on the semiconductor substrate 522. For example, a radial low emissivity zone may be rotated to positions of the semiconductor substrate with low deposition thicknesses, which may increase the heat reflected back to the support plate 520 and semiconductor substrate 522 to increase the film thickness at these positions. The bottom plate 530 may be rotated any number of times and held at each position for a same or different duration in order to make the film thickness on the semiconductor substrate 522 more uniform.

The bottom plate 530 may be rotated using various rotational actuators. In the embodiment illustrated in FIG. 5, the bottom plate 530 may be rotated by a drive assembly 540. Drive assembly 540 may include a rotational actuator, such as a step motor, which may rotate an outer magnet assembly 545. Outer magnet assembly 545 may be disposed beneath, alongside, and/or otherwise adjacent to the bottom plate 530 and may extend around the shaft 525. Outer magnet assembly 545 may be generally annular in shape and may include one or more magnets 550, which may be permanent and/or electromagnets. The magnets 550 may be disposed at various intervals about the outer magnet assembly 545. For example, a number of magnets 550 (or a single annular magnet) may be provided in a generally annular arrangement about the shaft 525. The outer magnet assembly 545 may be positioned atop an atmospheric bearing 555 that facilitates smooth rotation of the outer magnet assembly 545 and reduces wear between surfaces of the outer magnet assembly 545 and adjacent components that slide relative to one another during rotation of the outer magnet assembly 545.

The bottom plate 530 may include or otherwise be coupled with a drive shaft 560 that extends downward from the bottom plate 530 and is received within an interior of the outer magnet assembly 545. The drive shaft 560 may include an inner magnet assembly 565 that includes one or more magnets 570, which may be permanent and/or electromagnets. The magnets 570 may be disposed at various intervals about the inner magnet assembly 565. For example, a number of magnets 570 (or a single annular magnet) may be provided in a generally annular arrangement about the drive shaft 560. An inner bearing 575 may be disposed between a bottom end of the drive shaft 560 and a top of the outer magnet assembly 545 (and/or other component upon which the drive shaft 560 rests) that facilitates smooth rotation of the inner magnet assembly 565 and the outer magnet assembly 545 (or other component) and reduces wear between surfaces of the drive shaft 560 and the outer magnet assembly 545. As the outer magnet assembly 545 is rotated by the drive assembly 540, the magnetic force between the inner magnets 570 and outer magnets 550 causes the drive shaft 560 and bottom plate 530 to rotate. For example, the inner magnets 570 and outer magnets 550 may be arranged with opposing poles facing one another such that an attractive force exists between the inner magnets 570 and outer magnets 550 that enables the movement of the outer magnet assembly 545 to attract the inner magnetic assembly 565 and cause a corresponding rotation of the drive shaft 560. In other embodiments, the inner magnets 570 and outer magnets 550 may be arranged with the same poles facing one another such that a repulsive force exists between the inner magnets 570 and outer magnets 550 that enables the movement of the outer magnet assembly 545 to repel the inner magnetic assembly 565 and cause a corresponding rotation of the drive shaft 560.

Such rotation assembly designs not only effectively enable the bottom plate to be rotated to change the angular position of one or more emissivity zones, but also isolate drive components from vacuum conditions within the chamber 500. For example, only the drive shaft 560 and outer magnetic assembly 545 are exposed to the chamber vacuum, while the drive assembly 540 may be completely isolated from the vacuum. Such features help ensure that the chamber 500 remains free of outside contaminants which may otherwise be present with dynamic actuators being present within the vacuum and ensures that deposition gases do not contaminate the drive assembly 540.

In some embodiments, rather than using a rotatable outer magnet assembly 545, chamber 500 may operate as an AC motor. For example, the chamber 500 may include a fixed outer magnet assembly including a number of electromagnets, with one pole of each electromagnet facing the drive shaft of the bottom plate. The fixed outer magnet assembly may serve as a stator. An inner magnet assembly positioned within the drive shaft and at least partially aligned with the fixed outer magnet assembly may sever as a rotor. The polarity of the outer electromagnets may be adjusted to rotate the magnetic field of the stator, which causes the rotor (the drive shaft) and bottom plate to rotate.

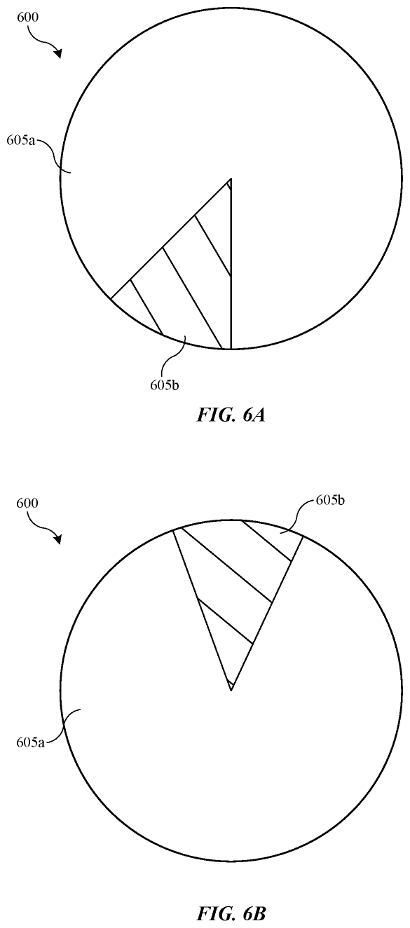

FIGS. 6A and 6B show schematic top plan views of an exemplary bottom plate 600 according to some embodiments of the present technology. The bottom plate 600 may be included in any chamber or system previously described (such as system 200 or 300 or chamber 500), as well as any other chamber or system that may benefit from the shielding. The bottom plate 600 has two emissivity zones 605. For example, the bottom plate 600 may have a primary emissivity zone 605a and a secondary emissivity zone 605b. One of the emissivity zones 605 may be a high emissivity zone and one of the emissivity zones 605 may be a low emissivity zone. For example, the primary emissivity zone 605a may be a high emissivity zone that takes up a majority of the surface area of the bottom plate 600 while the secondary emissivity zone 605b is a low emissivity zone, although this arrangement may be reversed in some embodiments. As illustrated, the secondary emissivity zone 605b is in the form of a wedge (although other radial and/or non-radial shapes are possible) while the primary emissivity zone 605a makes up a remaining portion of the bottom plate 600. The radial design of the secondary emissivity zone 605b simplifies the process for rotating the bottom plate to create more uniform film thickness, as placement of only one discrete emissivity zone 605b may be considered. For example, to increase film thickness at a first portion of a semiconductor substrate, a low-emissivity secondary emissivity zone 605b may be positioned beneath the first portion of the semiconductor substrate as shown in FIG. 6A. After a predetermined period of time, the bottom plate 600 may be rotated to a second position in which the secondary emissivity zone 605b is positioned beneath a second portion of the semiconductor substrate, such as shown in FIG. 6B. The bottom plate 600 may be left in this position for another period of time to radiate more heat back toward the semiconductor substrate to increase film thickness at the second portion. The rotation of the bottom plate 600 may be performed any number of times to any number of positions to produce a substantially uniform film thickness across the semiconductor substrate, with areas of the substrate with thinner film thickness having the secondary emissivity zone 605b positioned below for greater periods of time. It will be appreciated that a similar process may be performed with the secondary emissivity zone 605b being a high emissivity zone and the primary emissivity zone 605a being a low emissivity zone.

While shown with only two emissivity zones 605, it will be appreciated that some embodiments may incorporate more than two emissivity zones 605 into a bottom plate 600. For example, the bottom plate 600 may include about or greater than 2 emissivity zones, about or greater than 3 emissivity zones, about or greater than 4 emissivity zones, about or greater than 5 emissivity zones, about or greater than 6 emissivity zones, about or greater than 7 emissivity zones, about or greater than 8 emissivity zones, about or greater than 9 emissivity zones, or more. Additionally, while shown using a radial pattern for the secondary emissivity zone 605a, it will be appreciated that some embodiments may utilize other shapes, sizes, and/or arrangements of emissivity zones to provide more complex emissivity solutions.

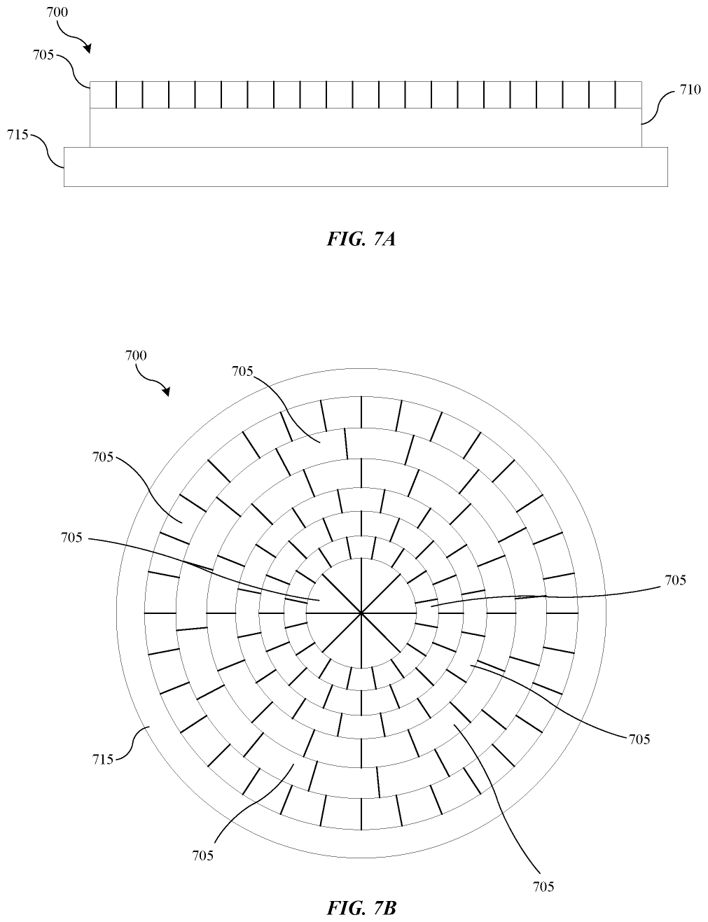

FIG. 7A shows a side cross-sectional view of an exemplary bottom plate 700 according to some embodiments of the present technology. The bottom plate 700 may be included in any chamber or system previously described (such as system 200 or 300 or chamber 500), as well as any other chamber or system that may benefit from the shielding. The bottom plate 700 may include a number of light emitting diodes (LEDs) 705 that project up from and/or form a top surface of the bottom plate 700. Control and power circuitry of the LEDs 705 may be provided within a housing 710 that is secured to a base 715 of the bottom plate 700. By maintaining the power and control circuitry within the housing 710, the circuitry may be protected from the various gases supplied to the chamber.

As shown in the top plan view of FIG. 7B, the LEDs 705 may be positioned in an array and may be configured to emit infrared (IR) light to actively heat a semiconductor substrate positioned on a support plate above the bottom plate 700. The LEDs 705 may be arranged in a uniform or non-uniform arrangement atop the bottom plate 700. The LEDs 705 may be individually controllable and/or controllable in groups to form different emissivity zones. For example, more power may be supplied to a first subset of the LEDs 705 to increase the amount of light, and subsequently heat, emitted by the first subset of LEDs 705 in the direction of the support plate, while a lower amount of power (or no power at all) may be supplied to a second subset of the LEDs 705 to reduce the amount of heat radiated toward corresponding locations of the support plate and semiconductor substrate. In some embodiments, a single fixed emissivity pattern may be produced by the LEDs 705 during a deposition operation. Other embodiments may include any number of adjustments to power of some or all of the LEDs 705 to tune the emissivity pattern of the bottom plate 705 and to achieve greater film residue uniformity. It will be appreciated that any number of subsets of one or more LEDs 705 may be used to create a particular emissivity pattern for the bottom plate 700 and that any number of LEDs 705 may be included on the bottom plate. For example, the bottom plate 700 may include about or greater than 100 LEDs, about or greater than 200 LEDs, about or greater than 300 LEDs, about or greater than 400 LEDs, about or greater than 500 LEDs, about or greater than 600 LEDs, about or greater than 700 LEDs, about or greater than 800 LEDs, about or greater than 900 LEDs, about or greater than 1000 LEDs, about or greater than 1500 LEDs, about or greater than 2000 LEDs, or more, with greater numbers of LEDs 705 providing more complex and precise control over the emissivity pattern and film uniformity.

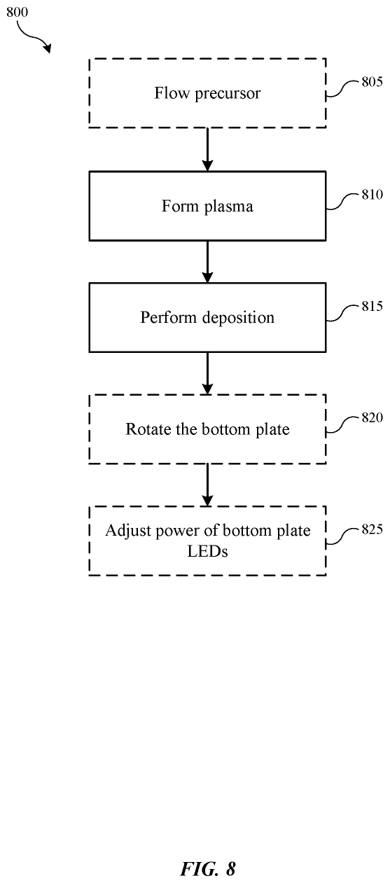

FIG. 8 shows operations of an exemplary method 800 of semiconductor processing according to some embodiments of the present technology. The method may be performed in a variety of processing chambers, including processing system 200 or 300 or chamber 500 described above, which may include bottom plates according to embodiments of the present technology, such as any bottom plate discussed previously. Method 800 may include a number of optional operations, which may or may not be specifically associated with some embodiments of methods according to the present technology.

Method 800 may include a processing method that may include operations for forming a hardmask film or other deposition operations. The method may include optional operations prior to initiation of method 800, or the method may include additional operations. For example, method 800 may include operations performed in different orders than illustrated. In some embodiments, method 800 may include flowing one or more precursors into a processing chamber at operation 805. For example, the precursor may be flowed into a chamber, such as included in system 200, and may flow the precursor through one or more of a gasbox, a blocker plate, or a faceplate, prior to delivering the precursor into a processing region of the chamber. In some embodiments the precursor may be or include a carbon-containing precursor.

In some embodiments, a bottom plate may be included in the system about the substrate support, such as about a shaft portion, where a substrate is positioned on a plate positioned above the bottom plate. Any of the other characteristics of bottom plates described previously may also be included, including any aspect of bottom plates 330, 400, 530, 600, and/or 700, such as the bottom plate having multiple emissivity zones having different emissivity levels. At operation 810, a plasma may be generated of the precursors within the processing region, such as by providing RF power to the faceplate to generate a plasma. Material formed in the plasma, such as a carbon-containing material, may be deposited on the substrate at operation 815.

Optionally, at block 820 the method may include rotating the bottom plate about the shaft to change an angular position of a first emissivity zone and a second emissivity zone. For example, the first emissivity zone may be repositioned to a first location for a first period of time, after which the first emissivity zone may be later repositioned to a second location for a second period of time after the first period of time has elapsed. The two periods of time may be the same or may be different based on a known residue pattern for the particular deposition recipe being used. For example, either the first period of time and/or the second period of time may be greater than or about 1 second, greater than or about 3 seconds, greater than or about 5 seconds, greater than or about 10 seconds, greater than or about 20 seconds, greater than or about 30 seconds, or more. To rotate the bottom plate, the chamber may include a drive assembly similar to drive assembly 540 described above. For example, the drive assembly may include an outer magnet assembly that may be rotated to drive rotation of an inner magnet assembly that is disposed within a drive shaft of the bottom plate.

In some embodiments, some or all of the various emissivity zones may be formed by LEDs that emit IR light. For example, a first emissivity zone may be formed from a first subset of LEDs and a second emissivity zone may be formed from a second subset of LEDs.

Optionally, at block 825 the method may include adjusting a power level of the first plurality of light emitting diodes and/or the second plurality of light emitting diodes to adjust an emissivity pattern of the bottom plate.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a region” includes a plurality of such regions, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
a chamber body comprising sidewalls and a base;
a substrate support extending through the base of the chamber body, wherein the substrate support comprises:
a support plate; and
a shaft coupled with the support plate; and
a bottom plate coupled with the shaft of the substrate support and extending below a bottom surface of the support plate, wherein:
the bottom plate comprises a first emissivity zone and a second emissivity zone; and
the first emissivity zone and the second emissivity zone have different emissivity levels.

2. The semiconductor processing system of claim 1, wherein:
one or both of the first emissivity zone and the second emissivity zone extend radially from a center of the bottom plate.

3. The semiconductor processing system of claim 1, wherein:
the first emissivity zone comprises a polished top surface.

4. The semiconductor processing system of claim 1, wherein:
the first emissivity zone comprises a textured top surface.

5. The semiconductor processing system of claim 1, wherein:
the first emissivity zone comprises a first material and the second emissivity zone comprises a different second material.

6. The semiconductor processing system of claim 1, wherein:
one or both of the first emissivity zone and the second emissivity zone are shaped based on a known residue pattern of a semiconductor substrate.

7. The semiconductor processing system of claim 1, wherein:
a distance between a bottom surface of the support plate and the first emissivity zone is different than a distance between the bottom surface of the support plate and the second emissivity zone.

8. The semiconductor processing system of claim 1, further comprising:
a drive mechanism that selectively rotates the bottom plate about the shaft to change an angular position of the first emissivity zone and the second emissivity zone.

9. The semiconductor processing system of claim 8, wherein:
the bottom plate is coupled with an inner magnet assembly;
the drive mechanism comprises an outer magnet assembly; and
the outer magnet assembly interacts with the inner magnet assembly to drive rotation of the bottom plate.

10. The semiconductor processing system of claim 9, wherein:
rotation of the outer magnet assembly causes the inner magnet assembly and the bottom plate to rotate.

11. The semiconductor processing system of claim 9, wherein:
one or both of the inner magnet assembly and the outer magnet assembly comprises an electromagnet.

12. A method of semiconductor processing, comprising:
flowing one or more precursors into a processing chamber, wherein the processing chamber comprises:
a substrate support comprising:
a support plate that supports a semiconductor substrate; and
a shaft coupled with the support plate; and
a bottom plate coupled with the shaft of the substrate support and extending below a bottom surface of the support plate, wherein:
the bottom plate comprises a first emissivity zone and a second emissivity zone; and
the first emissivity zone and the second emissivity zone have different emissivity levels;
generating a plasma of the precursor within the processing chamber; and
depositing a material on the semiconductor substrate.

13. The method of semiconductor processing of claim 12, further comprising:
rotating the bottom plate about the shaft to change an angular position of the first emissivity zone and the second emissivity zone.

14. The method of semiconductor processing of claim 13, wherein:
rotating the bottom plate about the shaft comprises repositioning the first emissivity zone to a first location for a first period of time and repositioning the first emissivity zone to a second location for a second period of time after the first period of time has elapsed.

15. The method of semiconductor processing of claim 13, wherein:
the processing chamber further comprises a drive mechanism having an outer magnet assembly;
the bottom plate is coupled with an inner magnet assembly; and
rotating the bottom plate about the shaft comprises rotating the outer magnet assembly to cause the inner magnet assembly and the bottom plate to rotate.

16. The method of semiconductor processing of claim 13, wherein:
the processing chamber further comprises a drive mechanism having an outer magnet assembly;
the bottom plate is coupled with an inner magnet assembly;
one or both of the inner magnet assembly and the outer magnet assembly comprises an electromagnet; and
rotating the bottom plate about the shaft comprises powering the electromagnet to rotate the inner magnet assembly and the bottom plate.

17. The method of semiconductor processing of claim 13, wherein:
a timing of rotation of the bottom plate is based on a residue pattern of the material on the semiconductor substrate.

18. The method of semiconductor processing of claim 12, wherein:
the first emissivity zone is formed from a first plurality of light emitting diodes directed toward the substrate support;
the second emissivity zone is formed from a second plurality of light emitting diodes directed toward the substrate support; and
the method further comprises adjusting a power level of one or both of the first plurality of light emitting diodes and the second plurality of light emitting diodes to adjust an emissivity pattern of the bottom plate.

19. A semiconductor processing system, comprising:
a chamber body comprising sidewalls and a base;
a substrate support extending through the base of the chamber body, wherein the substrate support comprises:
a support plate; and
a shaft coupled with the support plate; and
a bottom plate coupled with the shaft of the substrate support and extending below a bottom surface of the support plate, wherein:
a top surface of the bottom plate comprises a plurality of light emitting diodes (LEDs) that emit infrared light toward the substrate support.

20. The semiconductor processing system of claim 19, wherein:
each of the plurality of light emitting diodes is independently controllable.
